(19) United States
(12) Patent Application Publication
(10) Pub. No.: US 2008/0283982 A1
(43) Pub. Date: Nov. 20, 2008

(54) Multi-chip semiconductor device having leads and method for fabricating the same

(75) Inventors: Chung-Lun Liu, Taichung Hsien (TW); Chin-Huang Chang, Taichung Hsien (TW); Chien-Ping Huang, Taichung (TW); Chang-Yueh Chan, Taichung (TW); Chih-Ming Huang, Hsinchu Hsein (TW)

Correspondence Address: Edwards Angell Palmer & Dodge LLP, P.O. Box 55874, Boston, MA, 02205, US

(73) Assignee: Siliconware Precision Industries Co., Ltd, Taichung (TW)

(21) Appl. No.: 12/152,802

(22) Filed: May 15, 2008

(30) Foreign Application Priority Data
May 15, 2007 (TW) 096117165

(51) Int. Cl. H01L 21/58; H01L 23/495

(52) U.S. Cl. 257/673; 438/108; 257/E21.505; 257/E23.023

(57) ABSTRACT

The present invention proposes a multi-chip semiconductor device having leads and a method for fabricating the same. The method includes the steps of: providing a substrate having a plurality of connection pads disposed on a surface thereof; mounting a plurality of semiconductor chips on the surface of the substrate, and electrically connecting the semiconductor chips to the surface of the substrate; forming an encapsulant on the substrate to encapsulate the semiconductor chips and expose the connection pads to form a package unit; and providing a lead frame having a plurality of leads, and electrically connecting the connection pads exposed from the package unit to the leads of the lead frame to form a multi-chip semiconductor device having leads, thereby forming a multi-chip semiconductor device having leads. By the multi-chip semiconductor device and the method for fabricating the same as proposed in the present invention, problems like poor reliability caused by stress induced by several types of materials in a semiconductor package into which a substrate and leads are integrated, moisture absorption by an encapsulated substrate, and cracks developed as a result of moisture absorption by the substrate can be avoided.

### BACKGROUND OF THE INVENTION

1. Field of the Invention

The present invention relates to semiconductor devices and methods for fabricating the same, and more particularly, to a multi-chip semiconductor device having leads and a method for fabricating the same.

2. Description of Related Art

A conventional lead frame type semiconductor package, such as a quad flat package (QFP), is fabricated by attaching a chip to a lead frame having a die pad and a plurality of leads, electrically connecting a plurality of solder pads disposed on an upper surface of the chip to the corresponding leads via a plurality of bonding wires, and encapsulating the chip and the bonding wires by an encapsulant to form a lead frame type semiconductor package. Please refer to U.S. Pat. Nos. 5,874,773, 6,696,750, 6,902,102 and 7,057,293, for information on related techniques.

Moreover, in order to meet the increasing demand for miniaturization and high operation speed of electronic products by improving performance and capacity of a single semiconductor package, semiconductor packages having multi-chip modules (MCM), which typically integrate two or more chips in a single package structure to reduce an overall circuit volume and improve electrical performance of semiconductor packages, have become popular.

However, conventional lead frame type semiconductor packages as single layer structures cannot provide sufficient electrical connection among a plurality of chips mounted on a single-layered lead frame.

FIG. 1 is a cross-sectional diagram of a multi-chip semiconductor package according to Taiwanese Patent No. 1229427. As shown in FIG. 1, a substrate 12 is mounted on a die pad 111 of a lead frame 11 to form a multi-layer structure, a plurality of semiconductor chips 13 are horizontally mounted on the substrate 12, and the semiconductor chips 13 are then electrically connected to the substrate 12 and lead 112 of the lead frame 11 via a first bonding wire group 14a and a second bonding wire group 14b, respectively. A circuit predisposed on the substrate 12 electrically connects the semiconductor chips 13 to one another. Please refer to U.S. Pat. No. 5,502,289 and U.S. Pat. No. 5,661,337, for information on related techniques.

Nevertheless, in the above semiconductor package, reliability of interface between the substrate and the die pad of the lead frame is often adversely affected by a stress induced by different materials. Moreover, as the substrate material inside the semiconductor package readily absorbs moisture, the semiconductor package is prone to developing cracks. Additionally, disposal of a substrate on a die pad with a limited area cannot allow integration of multiple chips in a semiconductor package at the same time, thereby limiting uses of this type of multi-layer lead frame having a multi-layered structure.

FIG. 2 shows a BGA substrate having lead, according to U.S. Pat. Nos. 5,563,446 and 5,789,811, to resolve the above drawbacks. As shown in FIG. 2, a substrate 22 is integrated with a plurality of leads 21 therein, so as to allow a semiconductor chip 23 disposed on the substrate 22 to be electrically connected to the substrate 22 and the leads 21 at the same time via a plurality of bonding wires 24. An encapsulant 26 is subsequently formed on the substrate 22, for encapsulating the semiconductor chip 23 and the leads 21. The semiconductor chip 23 is further electrically connected to an external device via a plurality of solder balls 25 mounted on a bottom surface of the substrate 22 and the leads 21.

However, as the lead frame is integrated to the inside of the substrate, fabrication of the semiconductor package is difficult. Also, since the leads (which are made of metal) are disposed on the inside the resin substrate (which are made of resin), stress induced by different interfaces can result in poor reliability of the package.

Therefore, the problem to be solved herein is to provide a multi-chip semiconductor device and method for fabricating the same, which can integrate a plurality of semiconductor chips therein and solve problems such as stress induced by several types of materials, moisture absorption by an encapsulated substrate, and poor reliability caused by encapsulated leads.

### SUMMARY OF THE INVENTION

In light of the above drawbacks in the prior art, a primary objective of the present invention is to provide a multi-chip semiconductor device having leads and a method for fabricating the same, which is capable of integrating a plurality of semiconductor chips to form a MCM semiconductor device.

Another objective of the present invention is to provide a multi-chip semiconductor device having leads and a method for fabricating the same, which avoid drawbacks like poor reliability caused by a stress induced by different interfaces in a conventional semiconductor package.

Another objective of the present invention is to provide a multi-chip semiconductor device having leads and a method for fabricating the same, which avoid drawbacks like poor reliability caused by encapsulated leads in a conventional semiconductor package.

A further objective of the present invention is to provide a semiconductor device having leads and a method for fabricating the same, which avoid drawbacks like cracks developed due to moisture absorption by an encapsulated substrate in a conventional semiconductor package.

Still another objective of the present invention is to provide a multi-chip semiconductor device having leads and a method for fabricating the same, by which fabrication processes are simplified and cost-effective to implement.

In order to attain the above and other objectives, the present invention provides a method for fabricating a multi-chip semiconductor device having leads, comprising the steps of: providing a substrate having a plurality of connection pads disposed on a surface thereof; mounting a plurality of semiconductor chips on the surface of the substrate, and electrically connecting the semiconductor chips to the surface of the substrate; forming an encapsulant on the substrate to encapsulate the semiconductor chips and expose the connection pads to form a package unit; and providing a lead frame having a plurality of leads, and electrically connecting the exposed connection pads in the package unit to the leads of the lead frame to form a multi-chip semiconductor device having leads, thereby forming a multi-chip semiconductor device having leads.

The present invention further provides a multi-chip semiconductor device, comprising: a substrate having a plurality of connection pads disposed on a surface thereof; a plurality of semiconductor chips mounted on and electrically connected to the surface of the substrate; and encapsulant formed on the substrate to encapsulate the semiconductor chips and expose the connection pads; and a plurality of leads physically and electrically connected to the connection pads.

Moreover, a ring-shaped reinforcing element can be disposed on the leads to reinforce the connection between the leads and the substrate of the package unit. Alternatively, a heat dissipating element having a concave portion can be disposed on the leads and the top of the encapsulant, thereby increasing heat dissipation of the multi-chip semiconductor device and reinforcing the connection among the leads and the substrate. Furthermore, a plurality of solder balls can be mounted on a surface opposed to the surface where the encapsulant is formed, of the package unit, to provide an additional path for signal transmission and heat conduction. In addition, taken electrical requirements into consideration, a plurality of exposed solder pads with different electrical properties are formed on a surface opposed to the surface where the encapsulant is formed, so as to allow the multi-chip semiconductor device to be electrically connected to the when being mounted to an external device such as a printed circuit board (PCB). Therefore, by the multi-chip semiconductor device having leads and the method for fabricating the same, of the present invention, a substrate having a plurality of connection pads disposed on a surface thereof is provided, a plurality of semiconductor chips mounted on and electrically connected to the surface of the substrate, an encapsulant is formed to encapsulates the semiconductor chips and expose the connection pads to form a package unit, subsequently the exposed connection pads in the package unit are physically and electrically connected to the leads of the lead frame, to obtain a semiconductor device having a MCM and leads. The multi-chip semiconductor device of the present invention is fabricated by performing a simplified fabrication processes and is cost-effective. Moreover, unlike prior arts, the present invention can avoid poor reliability caused by a stress induced by several types of materials in a semiconductor package in which a substrate and leads are integrated, moisture absorption by an encapsulated substrate, and cracks developed as a result of moisture absorption by the substrate.

### BRIEF DESCRIPTION OF DRAWINGS

The present invention can be more fully understood by reading the following detailed description of the preferred embodiments, with reference made to the accompanying drawings, wherein:

FIG. 1 is a cross-sectional diagram of a multi-chip semiconductor package according to Taiwanese Patent No. 1229427;

FIG. 2 is a schematic diagram of a semiconductor package according to U.S. Pat. Nos. 5,563,446 and 5,789,811;

FIGS. 3A to 3E are schematic diagrams showing a multi-chip semiconductor device having leads and a method for fabricating the same according to a first embodiment of the present invention;

FIGS. 4A and 4B are schematic diagrams showing a multi-chip semiconductor device having leads and a method for fabricating the same according to a second embodiment of the present invention;

FIG. 5 is a schematic diagram showing a multi-chip semiconductor device having leads and a method for fabricating the same according to a third embodiment of the present invention;

FIG. 6 is a diagram showing a multi-chip semiconductor device having leads and method for fabricating the same according to a fourth embodiment of the present invention; and

FIG. 7 is a diagram showing a multi-chip semiconductor device having leads and a method for fabricating the same according to a fifth embodiment of the present invention.

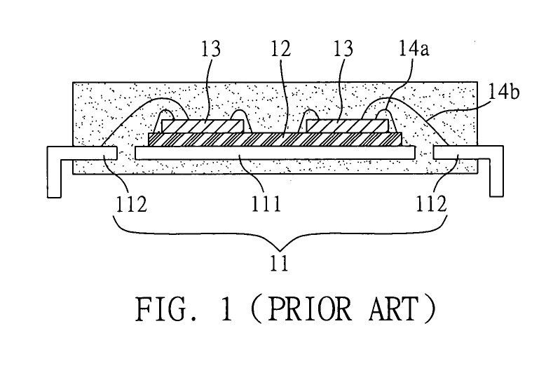

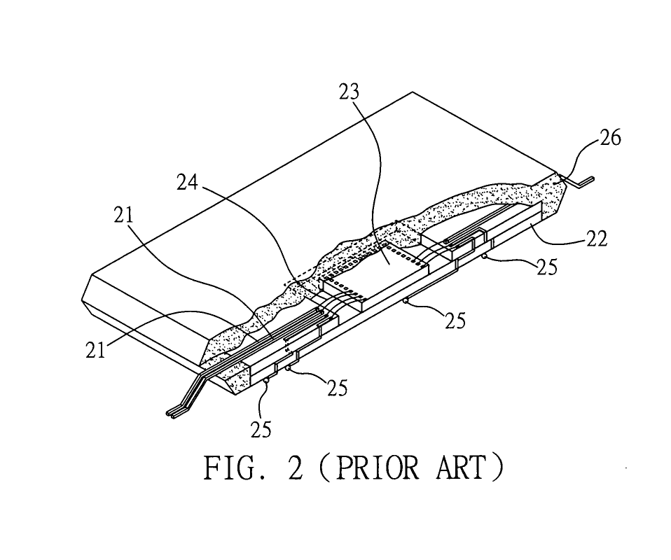

### DETAILED DESCRIPTION OF PREFERRED EMBODIMENTS

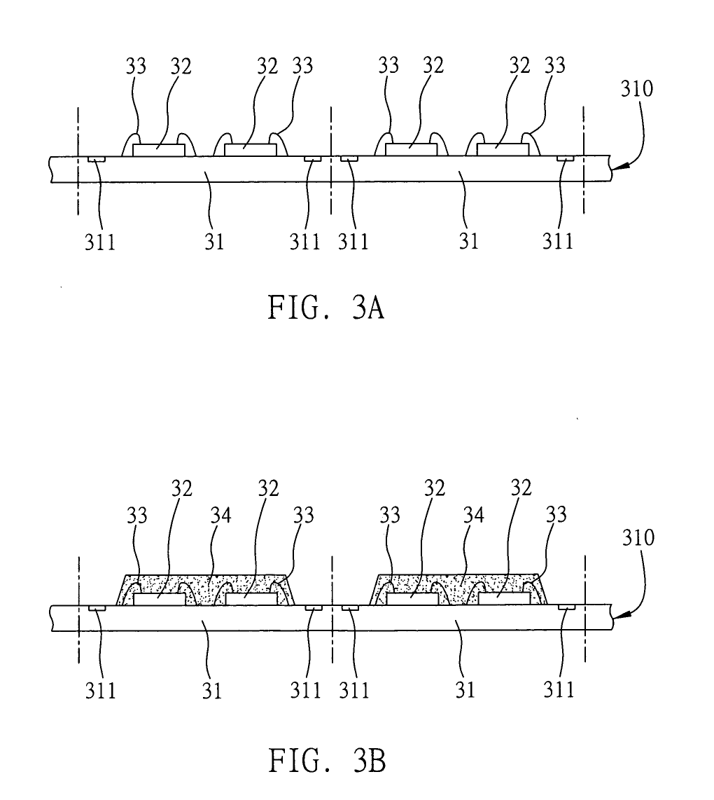

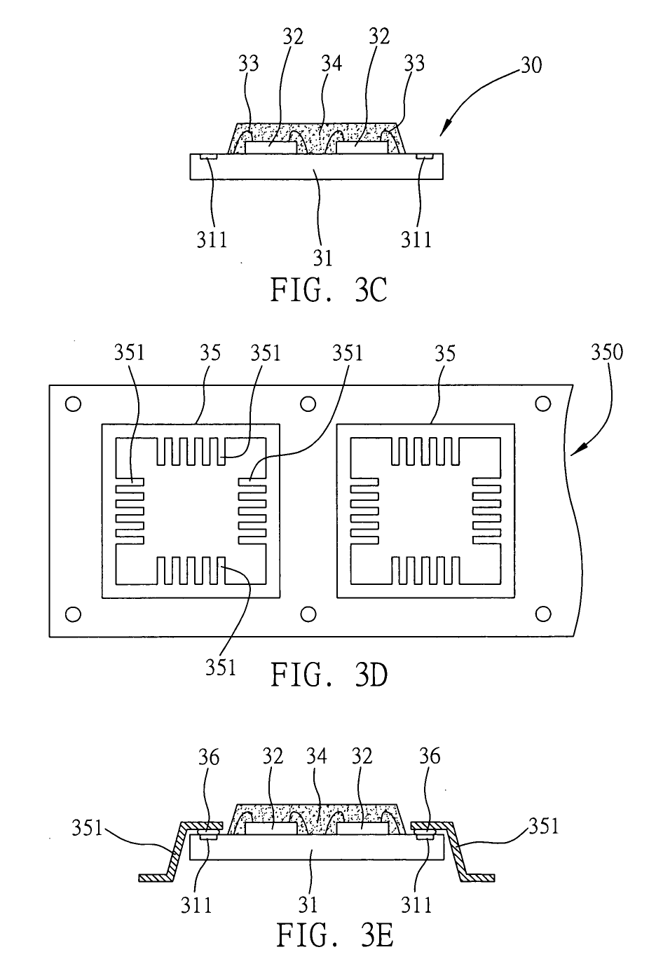

Embodiments of a multi-chip semiconductor device having leads and a method for fabricating the same proposed in the present invention are described as follows with reference to FIGS. 3 to 7. It should be understood that the drawing is a simplified schematic diagram only showing the components relevant to the present invention, and the layout of components could be more complicated in practical implementation.

### First Embodiment

FIGS. 3A to 3E are schematic diagrams showing a multi-chip semiconductor device having leads and a method for fabricating the same according to a first embodiment of the present invention. In this embodiment, a batch-type method is employed to fabricate the multi-chip semiconductor device having leads. It should be understood that the multi-chip semiconductor device having leads of the present invention can also be fabricated in a singular-type manner under suitable fabrication conditions.

Referring to FIG. 3A, a substrate module plate 310 having a plurality of substrates 31 is provided. A plurality of connection pads 311 are disposed on a surface of each of the substrates 31, for mounting a plurality of semiconductor chips 32 on each of the substrates 31, wherein the connection pads 311 are disposed on edges of the substrates 31. The semiconductor chips 32 can be electrically connected to the substrates 31, via a plurality of bonding wires 33 or by a flip-chip process.

Referring to FIGS. 3B and 3C, an encapsulate 34 is formed on each of the substrates 31 to encapsulate the semiconductor chips 32 and the bonding wires 33, and the connection pads 311 are exposed from the encapsulates 34.

Next, a singulation process is performed along the substrate module plate 31 to form a plurality of package units 30.

Referring to FIGS. 3D and 3E, a lead frame module 350 having a plurality of lead frames 35 are provided, wherein each of the lead frames 35 has a plurality of leads 351. By a reflow soldering process or a thermocompression bonding process, the connection pads 311 exposed from the encapsulants 34 of the package units 30 having previously encapsulated chips are electrically connected to the leads 351 via a conductive material 36 therebetween. Subsequently, lead forming is performed to the leads 351, and a singulation process is performed along the lead frames 35 to separate them from the lead frame module 350, thereby obtaining a plurality of multi-chip semiconductor devices having leads.

The leads 351 can be bent beforehand, so as to allow the package units 30 to be directly separated from the leads 351 after being connected to them, thereby forming a plurality of multi-chip semiconductor devices having the leads.

By the foregoing fabrication method, the present invention further provides a multi-chip semiconductor device having leads, comprising: a substrate 31 having a plurality of connection pads 311 disposed on a surface thereof; a plurality of semiconductor chips 32 mounted on and electrically connected to the substrate 31; an encapsulant 34 formed on the substrate 31 to encapsulate the semiconductor chips 32 and expose the connection pads 311; and a plurality of leads 351 physically and electrically connected with the connection pads 311.

By the multi-chip semiconductor device having leads and the method for fabricating the same, of the present invention, a substrate having a plurality of connection pads disposed on a surface thereof is provided, a plurality of semiconductor chips mounted on and electrically connected to the substrate are provided, an encapsulant is formed to encapsulate the semiconductor chips and expose the connection pads to form a package unit, subsequently the exposed connection pads in the package unit are physically and electrically connected to the leads of the lead frame, thereby obtaining a semiconductor device having a MCM and leads. The multi-chip semiconductor device of the present invention is fabricated by performing simplified fabrication processes and is cost-effective. Moreover, unlike prior arts, the present invention can avoid poor reliability caused by a stress induced by several types of materials in a semiconductor package in which a substrate and leads are integrated, moisture absorption by an encapsulated substrate, and cracks developed as a result of moisture absorption by the substrate.

### Second Embodiment

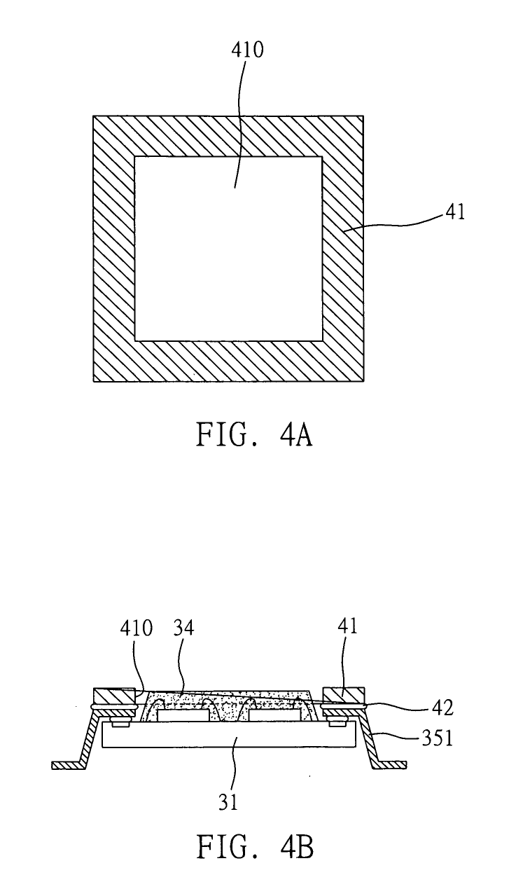

FIGS. 4A and 4B are schematic diagrams showing a multi-chip semiconductor device having leads and a method for fabricating the same according to a second embodiment of the present invention, wherein elements that are same as or similar to the above-described elements are denoted by the same reference numerals to facilitate illustration and understanding.

The major difference between the present embodiment and the first embodiment is that after the connections pads exposed from the encapsulant of the package unit is electrically connected to the leads of the lead frame, a ring-shaped reinforcing element 41 is disposed on the leads 351 via a non-conductive medium 42, and the encapsulant 34 of the package unit is accommodated in a ring-shaped opening 410 of the reinforcing element 41, thereby reinforcing the connection between the leads 351 and the substrate 31 of the package unit.

### Third Embodiment

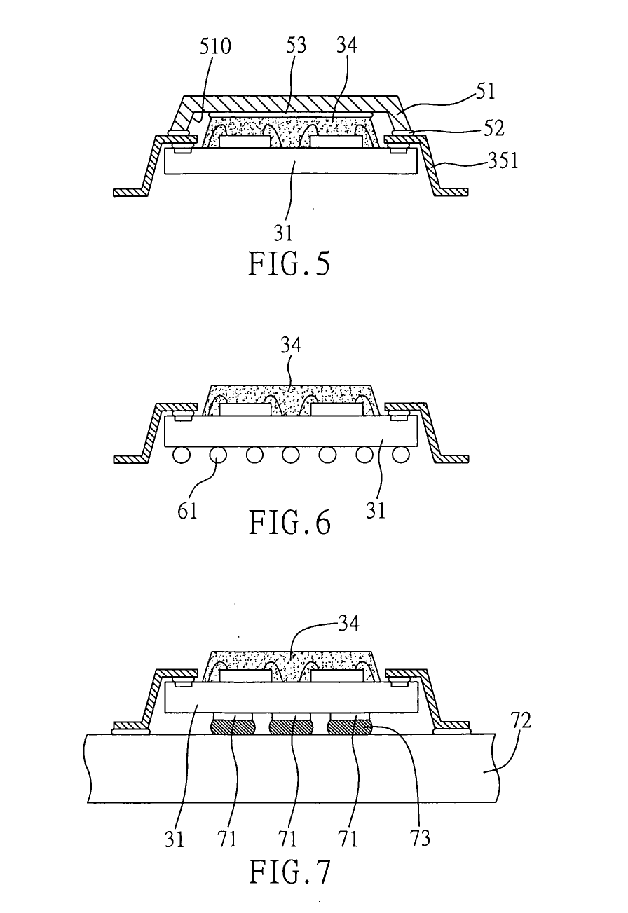

FIG. 5 is a schematic diagram showing a multi-chip semiconductor device having leads and a method for fabricating the same according to a third embodiment of the present invention, wherein elements that are same as or similar to the above-described elements are denoted by the same reference numerals to facilitate illustration and understanding.

The major difference between the present embodiment and the previous embodiments is that after the connections pads exposed from the encapsulant of the package unit is electrically connected to the leads of the lead frame, a heat dissipating element 51 having a concave portion 510 is disposed on the leads 351 via a non-conductive medium 52. The concave portion 510 and is mounted on the encapsulant 34 via a thermal conductive medium 53 therebetween (i.e., the thermal conductive medium 53 is in contact with the top of the concave portion 510 and the top of the encapsulant 34), thereby increasing heat dissipation of the multi-chip semiconductor device and reinforcing the connection among the leads 351 and the substrate 31.

### Fourth Embodiment

FIG. 6 is a diagram showing a multi-chip semiconductor device having leads and method for fabricating the same according to a fourth embodiment of the present invention, wherein elements that are same as or similar to the above-described elements are denoted by the same reference numerals to facilitate illustration and understanding.

The major difference between the present embodiment and the previous embodiments is that a plurality of solder balls 61 are mounted on a surface opposed to the surface where the encapsulant 34 is formed, of the substrate 31, to provide an additional path for signal transmission and heat conduction, thereby enhancing electrical performance and heat dissipation of the multi-chip semiconductor device.

### Fifth Embodiment

FIG. 7 is a diagram showing a multi-chip semiconductor device having leads and a method for fabricating the same according to a fifth embodiment of the present invention, wherein elements that are same as or similar to the above-described elements are denoted by the same reference numerals to facilitate illustration and understanding.

The major difference between the present embodiment and the previous embodiments is that a plurality of exposed solder balls 71 with different electrical properties are mounted on a surface opposed to the surface where the encapsulant 34 is formed, of the substrate 31, so as to allow the exposed solder balls 71 to be electrically connected to an external device 72 via a conductive material 73 therebetween when the multi-chip semiconductor device are mounted to the external device 72, thereby becoming a multi-voltage design or a ground design.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a multi-chip semiconductor device having leads, comprising the steps of:
providing a substrate having a plurality of connection pads disposed on a surface thereof, mounting a plurality of semiconductor chips on the surface of the substrate, and electrically connecting the semiconductor chips to the surface of the substrate;
forming an encapsulant on the substrate to encapsulate the semiconductor chips, and exposing the connection pads from the encapsulant to form a package unit; and
providing a lead frame having a plurality of leads, and electrically connecting the exposed connection pads in the package unit to the leads of the lead frame to form a multi-chip semiconductor device having leads.

2. The method of claim 1, wherein the multi-chip semiconductor device having leads is fabricated by one of a batch-type fabrication process and a singular-type fabrication process.

3. The method of claim 1, wherein each of the semiconductor chips is electrically connected to the substrate by one of a wire bonding process and a flip-chip process.

4. The method of claim 1, wherein each of the connection pads is disposed on an edge of the substrate.

5. The method of claim 1, wherein the package unit uses the exposed connection pads to be electrically connected to the leads via a conductive material therebetween, by employing one of a reflow soldering process and a thermocompression bonding process.

6. The method of claim 1, further comprising disposing a ring-shaped reinforcing element disposed on the leads via a non-conductive medium, and the encapsulant of the package unit is accommodated in an opening of the ring-shaped reinforcing element.

7. The method of claim 1, further comprising a heat dissipating element having a concave portion, the heat dissipating element is disposed on the leads via a non-conductive medium, and the concave portion is mounted on the encapsulant via a thermal conductive medium therebetween, wherein the thermal conductive medium is in contact with a top of the concave portion and a top of the encapsulant.

8. The method of claim 1, wherein a plurality of solder balls are mounted on a surface opposed to the surface where the encapsulant is formed, of the substrate, to provide a path for signal transmission and heat conduction.

9. The method of claim 1, wherein a plurality of exposed solder balls with different electrical properties are mounted on a surface opposed to the surface where the encapsulant is formed, of the substrate, so as to allow the exposed solder balls to be electrically connected to an external device via a conductive material therebetween to become a multi-voltage design or a ground design.

10. A multi-chip semiconductor device having leads, comprising:
a substrate having a plurality of connection pads disposed on a surface thereof;
a plurality of semiconductor chips mounted on and electrically connected to the substrate;
an encapsulant formed on the substrate to encapsulate the semiconductor chips and expose the connection pads; and
a plurality of leads physically and electrically connected to the connection pads.

11. The device of claim 10, wherein each of the semiconductor chips is electrically connected to the substrate by one of a wire bonding process and a flip-chip process.

12. The device of claim 10, wherein each of the connection pads is disposed on an edge of the substrate.

13. The device of claim 10, wherein the package unit uses the exposed connection pads to be electrically connected to the leads via a conductive material therebetween, by employing one of a reflow soldering process and a thermocompression bonding process.

14. The device of claim 10, further comprising disposing a ring-shaped reinforcing element disposed on the leads via a non-conductive medium, and the encapsulant of the package unit is accommodated in an opening of the ring-shaped reinforcing element.

15. The device of claim 10, further comprising a heat dissipating element having a concave portion, the heat dissipating element is disposed on the leads via a non-conductive medium, and the concave portion is mounted on the encapsulant via a thermal conductive medium therebetween, wherein the thermal conductive medium is in contact with a top of the concave portion and a top of the encapsulant.

16. The device of claim 10, wherein a plurality of solder balls are mounted on a surface opposed to the surface where the encapsulant is formed, of the substrate, to provide a path for signal transmission and heat conduction.

17. The device of claim 10, wherein a plurality of exposed solder balls with different electrical properties are mounted on a surface opposed to the surface where the encapsulant is formed, of the substrate, so as to allow the exposed solder balls to be electrically connected to an external device via a conductive material therebetween to become a multi-voltage design or a ground design.
